(19) United States
(12) Patent Application Publication
(10) Pub. No.: US 2007/0015319 A1
(43) Pub. Date: Jan. 18, 2007

(54) Method for forming contact hole and method for fabricating thin film transistor plate using the same

(75) Inventors: Hong-kee Chin, Suwon-si (KR); Sang-gab Kim, Seoul (KR); Min-seok Oh, Yongin-si (KR); Yu-gwang Jeong, Yongin-si (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/484,934

(22) Filed: Jul. 12, 2006

(30) Foreign Application Priority Data
Jul. 15, 2005 (KR) 10-2005-0064490

(51) Int. Cl. H01L 21/84

(52) U.S. Cl. 438/149; 257/E21.32

(57) ABSTRACT

A method for forming a contact hole includes forming a conductive layer on a substrate, patterning the conductive layer to form a wiring, forming an insulating layer on the wiring and the substrate through a low temperature process, and dry etching the insulating layer using an anoxic gas to expose the wiring.

This application claims priority from Korean Patent Application No. 10-2005-0064490 filed on Jul. 15, 2005, the disclosure of which is incorporated by reference in its entirety herein.

### BACKGROUND OF THE INVENTION

1. Technical Field

The present disclosure relates to a method for forming a contact hole, and more particularly, to a method for forming a contact hole using dry etching and a method for fabricating a TFT plate including the contact hole.

2. Discussion of the Related Art

A liquid crystal display (“LCD”) is a widely used flat panel display. The LCD may include two panels having electrodes and a liquid crystal layer interposed therebetween. The LCD applies voltages to the electrodes to rearrange the liquid crystal molecules in the liquid crystal layer, thereby adjusting the transmitted amount of incident light.

An LCD including electrodes on respective panels and thin film transistors (“TFTs”) for switching the voltages applied to the electrodes is widely used. The TFTs can be provided on one of the two substrates. In the LCD, a plurality of pixel electrodes can be arranged in a matrix at one substrate and a common electrode can be formed on the surface of the other substrate. An image is displayed on the LCD by applying individual voltages to the respective pixel electrodes. To apply the individual voltages, a plurality of three-terminal TFTs are connected to the respective pixel electrodes, and a plurality of gate lines transmitting signals for controlling the TFTs and a plurality of data lines transmitting voltages to be applied to the pixel electrodes are provided on the substrate.

As the display area of the LCD increases, the gate lines and the data lines connected to the TFTs become longer, thereby increasing resistance of the gate and data lines. To minimize a signal delay that can be caused by the resistance, the gate lines and the data lines can be formed of a material having low resistivity.

A silver (Ag) wiring having resistivity, of about 1.59 μΩcm can be used to reduce the signal delay problem of the gate lines and data lines. However, when Ag is used for a wiring, a subsequent process of, for example, forming an insulating layer should be performed at a low temperature due to the high heat sensitivity of the Ag. An insulating layer formed at a low temperature can have poor mechanical characteristics. When such an insulating layer is dry etched to form a contact hole, an etch rate is difficult to control and, for example, an undercut causing an inverse tapered profile may occur. In addition, a gate wiring or a data wiring subjected to an etching process may be oxidized and discolored.

### SUMMARY OF THE INVENTION

Exemplary embodiments of the present invention provide a method for forming a contact hole with a controlled etch rate.

Exemplary embodiments of the present invention provide a method for forming a contact hole, wherein a metal wiring under the contact hole is prevented from being oxidized.

According to an embodiment of the present invention, a method for forming a contact hole includes forming a conductive layer on a substrate, patterning the conductive layer to form a wiring, forming an insulating layer on the wiring and the substrate through a low temperature deposition process, and dry etching the insulating layer using an anoxic gas to expose the wiring.

The wiring may comprise silver (Ag).

The anoxic gas may include a fluorine based gas and a nitrogen gas.

The fluorine based gas may include at least one of SF₆, CF₄, CHF₃, or C₂F₆.

The mixing ratio of the fluorine based gas to the nitrogen gas can be in a range of about 2:1 to about 4:1.

The dry etching may include plasma etching.

The lateral profile of the contact hole may be substantially a right angle.

The low temperature deposition process can be performed at a temperature of about 280° C. or lower.

The low temperature process may include plasma chemical vapor deposition.

The insulating layer may include an organic layer, a low temperature amorphous silicon oxide layer, or a low temperature amorphous silicon nitride layer.

According to an embodiment of the present invention, a method for fabricating a thin film transistor (TFT) plate includes forming a gate wiring including a gate line that extends in a first direction on a substrate, forming a first insulating layer covering the gate wiring using a first low temperature deposition process, forming a data wiring including the data line that extends in a second direction to intersect the gate line on the first insulating layer, forming a second insulating layer covering the data wiring using a second low temperature deposition process, and forming a contact hole that exposes the gate wiring or the data wiring by dry etching the first insulating layer and the second insulating layer or by dry etching the second insulating layer using an anoxic gas.

### BRIEF DESCRIPTION OF THE DRAWINGS

Exemplary embodiments of the present invention can be understood in more detail from the following description taken in conjunction with the accompanying drawings, in which:

FIG. 1 is a flowchart of a method for forming a contact hole according to an embodiment of the present invention;

FIGS. 2 through 6 are cross-sectional views showing a method for forming a contact hole according to an embodiment of the present invention;

FIG. 7A is a layout of a thin film transistor (TFT) plate fabricated according to an embodiment of the present invention;

FIG. 7B is a cross-sectional view taken along the line B-B′ of FIG. 7A;

FIGS. 8A, 9A, 10A, and 11A are layouts sequentially showing a method for fabricating a TFT plate according to an embodiment of the present invention; and

FIGS. 8B, 9B, 10B, and 11B are cross-sectional views taken along the lines B-B′ of FIGS. 8A, 9A, 10A, and 11A.

### DETAILED DESCRIPTION OF THE EXEMPLARY EMBODIMENTS

Exemplary embodiments of the present invention will be described below in more detail with reference to the accompanying drawings. The present invention may, however, be embodied in many different forms and should not be construed as being limited to the embodiments set forth herein.

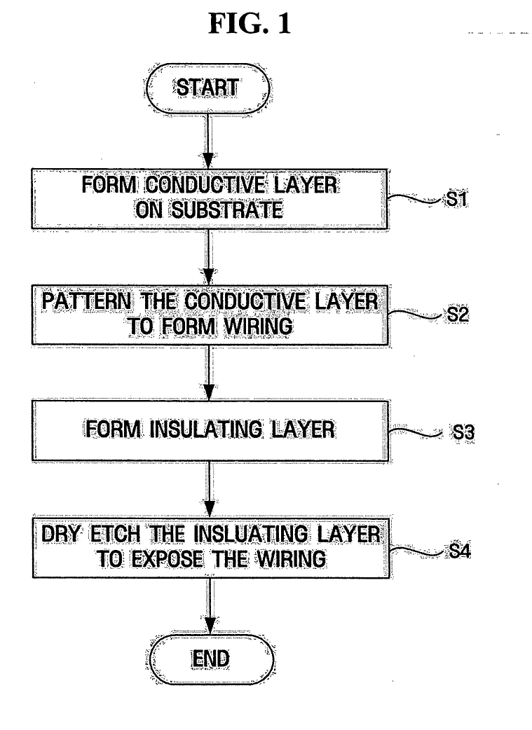

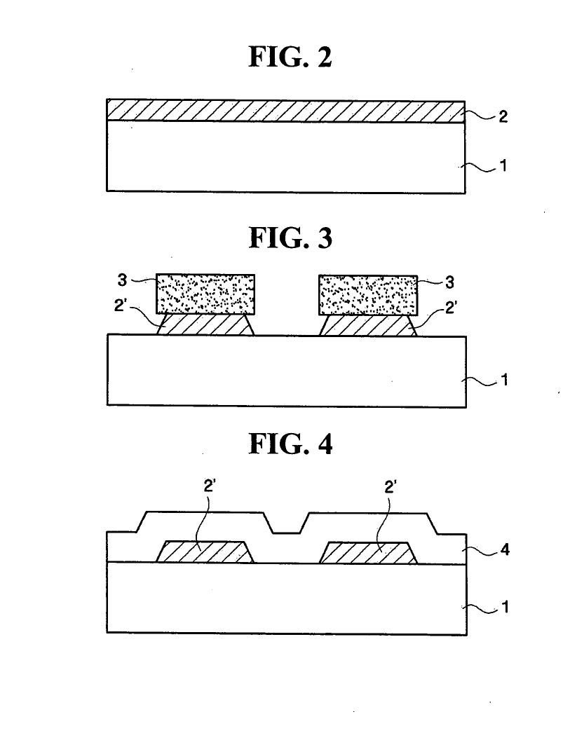

A method for forming a contact hole according to an embodiment of the present invention is described with reference to the accompanying drawings. FIG. 1 is a flowchart of a method for forming a contact hole according to an embodiment of the present invention, and FIGS. 2 through 6 are cross-sectional views showing a method for forming a contact hole according to an embodiment of the present invention.

Referring to FIGS. 1 and 2, a conductive layer 2 is formed on a substrate 1 (S1). The conductive layer 2 may include, for example, Ag or an Ag alloy. The conductive layer 2 is referred to as an “Ag conductive layer” hereinafter. The substrate 1 may be an insulating layer comprising, for example, glass, quartz, or sapphire. Before the Ag conductive layer 2 is formed on the substrate 1, a transparent conductive oxide layer (not shown) comprising, for example, an indium oxide material such as indium tin oxide (ITO) or indium zinc oxide (IZO) may be provided to improve adhesion of the Ag conductive layer 2 to the substrate 1.

The Ag conductive layer 2 can be formed on the substrate 1 by, for example, sputtering. In an embodiment of the present invention, the Ag conductive layer 2 has a thickness of about 1000 Å to about 3000 Å, preferably about 1500 Å to about 2000 Å. To increase adhesion between the Ag conductive layer 2 and an overlying insulation layer and to prevent Ag from being diffused into the overlying layer, a transparent conductive layer (not shown) may be formed on the Ag conductive layer 2.

Referring to FIGS. 1 and 3, the Ag conductive layer 2 is patterned to form a wiring (S2). A photosensitive layer is formed on the substrate 1 on which the Ag conductive layer 2 is formed. The photosensitive layer is then exposed and developed, thereby forming a photosensitive layer pattern 3. The Ag conductive layer 2 is then patterned using the photosensitive layer pattern 3 as an etching mask to form a metal wiring 2′ including, for example, Ag. The metal wiring 2′ is referred to as an “Ag wiring” hereinafter. In an embodiment of the present invention, the patterning of the Ag conductive layer 2 may be performed by wet etching.

Referring to FIGS. 1 and 4, an insulating layer 4 is formed (S3). The insulating layer 4 is formed on the entire surface of the substrate 1 on which the Ag wiring 2′ is formed. Since the Ag wiring 2′ is sensitive to heat, when a subsequent process is performed at a high temperature, agglomeration or short-circuiting may occur.

In an embodiment of the present invention, the insulating layer 4 formed on the Ag wiring 2′ may be deposited at a temperature of about 280° C. or lower. The insulating layer 4 may be formed of, for example, an organic layer, a low-temperature amorphous silicon oxide layer, or a low-temperature amorphous silicon nitride layer. In an embodiment of the present invention, the organic layer may comprise, for example, PerFluoroCycloButane (PFCB), BenzoCycloButene (BCB) or acryl. The low-temperature amorphous silicon oxide layer or the low-temperature amorphous silicon nitride layer may comprise, for example, Plasma Enhanced Chemical Vapor Deposition (PECVD). The organic layer may be formed by, for example, a spin coating method or a spinless coating method.

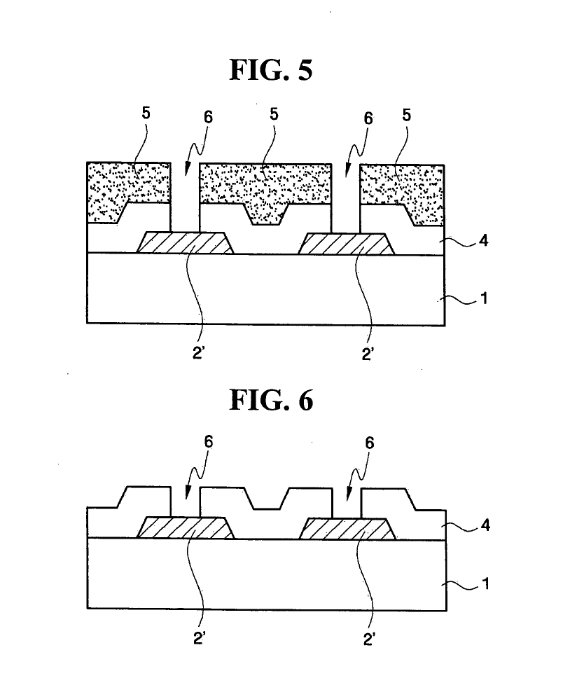

Referring to FIG. 1 and FIG. 5, the insulating layer 4 is etched to expose a wiring (S4). A photosensitive layer is formed on the insulating layer 4 and is then exposed and developed to form a photosensitive layer pattern 5. Next, the insulating layer 4 is patterned using the photosensitive layer pattern 5 as an etching mask, thereby forming a contact hole 6 to expose the Ag wiring 2′. In an embodiment of the present invention, patterning of the insulating layer 4 can be performed using dry etching including, for example, plasma etching. Plasma etching may be performed by, for example, a plasma etch (PE) mode device. A power signal is applied to an upper portion of the PE mode device. When plasma etching is performed by the PE mode device, damage to the substrate 1 or the Ag wiring 2′ can be minimized and an etching selectivity with respect to the photosensitive layer pattern 5 can be lowered. When plasma etching is performed by the PE mode device, pressure may be in a range of about 200 mT to about 500 mT.

The insulating layer 4 formed by a low temperature deposition process is not solid as compared to the insulating layer formed by a high temperature deposition process. Thus, when a contact hole is formed by patterning the insulating layer 4 through plasma etching using an oxygen gas, an etch rate can be about 30000 Å/min. Thus, controlling an etch rate is difficult. Moreover, since the lateral profile of the contact hole can be inversely tapered, corrosion of the metal wiring under the insulating layer may occur. Thus, the metal wiring is oxidized and discolored.

In a method for forming a contact hole according to an embodiment of the present invention, an anoxic gas including a fluorine based gas and a nitrogen (N₂) gas can be used in plasma etching. The fluorine based gas reacts with the insulating layer 4 by direct etching and may comprise at least one selected from the group of SF₆, CF₄, CHF₃, or C₂F₆. The nitrogen (N₂) gas can be used in place of a highly reactive oxygen (O₂) gas to control an etch rate of the insulating layer 4 that is not solid enough. For example, when plasma etching is performed on a low-temperature insulating layer using an etching gas including a nitrogen gas, an etch rate may be about 10000 Å/min. In an embodiment of the present invention, the mixing ratio of the fluorine based gas to the nitrogen (N₂) gas may be, for example, in a range of about 2:1 to about 4:1, and may vary with the hardness or thickness of the insulating layer 4. When the insulating layer 4 is patterned through plasma etching using the etch gas to form the contact hole 6 according to an embodiment of the present invention, the lateral profile of the contact hole 6 is a substantially right angle. Moreover, the Ag wiring 2′ exposed by the contact hole 6 is not oxidized by a plasma etching gas, and the Ag wiring 2′ is not discolored.

Referring to FIG. 6, the photosensitive layer pattern 5 is removed from the insulating layer 4.

The contact hole forming method according to an embodiment of the present invention may be applied to, for example, a TFT substrate for use in a liquid crystal display or an organic EL, a semiconductor element, or a semiconductor device.

A method for fabricating a thin film transistor (TFT) plate using the method for forming a contact hole according to an embodiment of the present invention is described with reference to the accompanying drawings.

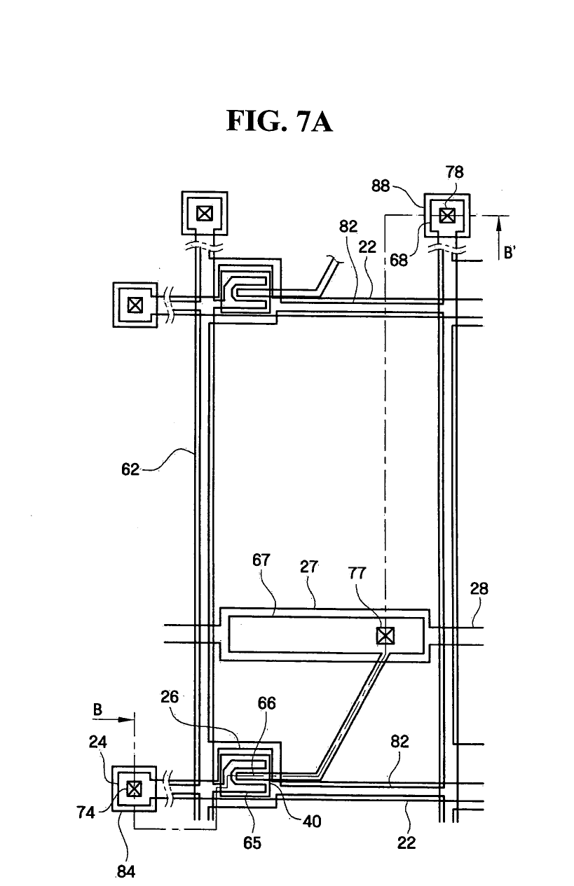

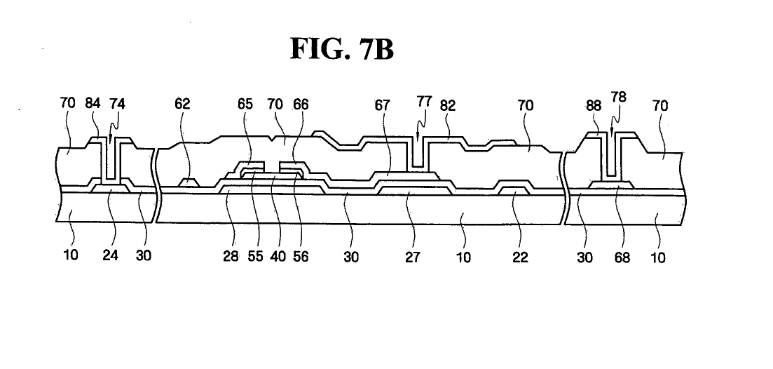

A structure of the TFT plate fabricated using the method for forming a contact hole according to an embodiment of the present invention is described with reference to FIGS. 7A and 7B. FIG. 7A is a layout of a thin film transistor (TFT) plate fabricated by a method according to an embodiment of the present invention, and FIG. 7B is a cross-sectional view taken along the line B-B′ of FIG. 7A.

As shown in FIGS. 7A and 7B, a plurality of gate wirings that transmit a gate signal is formed on an insulating substrate 10. The gate wirings include a gate line 22 that extends horizontally, a gate pad 24 that is connected to the end of the gate line 22 to receive a gate signal from the outside and transmits the same to the gate line 22, a gate electrode 26 of a protruding TFT that is connected to the gate line 22, and a storage electrode 27 and a storage electrode line 28 formed parallel with the gate line 22. The storage electrode line 28 extends horizontally across a pixel region and is connected to the storage electrode 27 that is wider than the storage electrode line 28. The storage electrode 27 overlaps a drain electrode extension portion 67 connected with a pixel electrode 82 to form a storage electric condenser that improves an electric charge retention capability of a pixel. The storage electrode 27 and the storage electrode line 28 may be modified in various manners in their shape and arrangement according to embodiments of the present invention.

The gate wirings 22, 24, 26, 27, and 28 may be formed of, e.g., an Ag conductive layer. To improve the adhesion with the substrate 10, a transparent conductive oxide layer (not shown) may comprise, for example, indium oxide such as ITO or IZO between the gate wirings 22, 24, 26, 27, and 28 and the substrate 10. The transparent conductive oxide layer (not shown) may be formed on the gate wirings 22, 24, 26, 27, and 28 to improve adhesion with respect to an upper layer such as a gate insulating layer 30 and to prevent Ag from diffusing into the upper layer.

The gate insulating layer 30 may comprise, for example, silicon nitride (SiNx) or silicon oxide (SiO2) on the substrate 10 and the gate wirings 22, 24, 26, 27, and 28. In an embodiment of the present invention, silicon nitride may be low-temperature amorphous silicon nitride and silicon oxide may be low-temperature amorphous silicon oxide.

A semiconductor layer 40 may comprise, for example, amorphous silicon hydride or polycrystalline silicon in the shape of an island on the gate insulating layer 30 on the gate electrode 26. Ohmic contact layers 55 and 56 may comprise, for example, silicide or n+ amorphous silicon hydride having a highly doped n-type impurity, on the semiconductor layer 40.

Data wirings are formed on the ohmic contact layers 55 and 56 and the gate insulating layer 30. The data wirings include a data line 62 that is formed in a longitudinal direction and intersects the gate line 22 to define a pixel, a source electrode 65 that is a branch of the data line 62 and extends onto the ohmic contact layer 55, a data pad 68 that is connected to an end of the data line 62 and receives an image signal from the outside, a drain electrode 66 that is separated from the source electrode 65 and is formed on the ohmic contact layer 56 opposite to the source electrode 65 on the gate electrode 26 or a channel portion of a TFT, and a drain electrode extension portion 67 with a large enough area that extends from the drain electrode 66 and overlaps the storage electrode 27.

The data wirings 62, 65, 66, 67, and 68 may be formed of, for example, an Ag conductive layer. To improve adhesion with a lower layer, e.g., the gate insulating layer 30, a transparent conductive oxide layer (not shown) may comprise, for example, indium oxide such as ITO or IZO between the data wirings 62, 65, 66, 67, and 68 and the gate insulating layer 30. In addition, to increase adhesion between the data wirings 62, 65, 66, 67 and 68 and an overlying insulation layer, e.g., a passivation layer 70, and to prevent Ag from being diffused into the overlying layer, the transparent conductive layer (not shown) may be formed on the data wirings 62, 65, 66, 67, and 68.

The source electrode 65 has at least a portion that overlaps the semiconductor layer 40. The drain electrode 66 is located opposite the source electrode 65 on the gate electrode 26 and has at least a portion that overlaps the semiconductor layer 40. The ohmic contact layers 55 and 56 exist between the semiconductor layer 40 and the source electrode 65 and between the semiconductor layer 40 and the drain electrode 66 to reduce contact resistances therebetween.

The drain electrode extension portion 67 overlaps the storage electrode 27 to form a storage capacitor between the storage electrode 27 and the gate insulating layer 30. In an embodiment of the present invention, when the storage electrode 27 is not formed, the drain electrode extension portion 67 is not formed either.

A passivation layer 70 is formed on the data wirings 62, 65, 66, 67, and 68 and portions of the semiconductor layer 40 that are not covered by the data wirings 62, 65, 66, 67, and 68. In an embodiment of the present invention, when the passivation layer 70 is formed using low-temperature amorphous silicon oxide or low-temperature amorphous silicon nitride, plasma chemical vapor deposition can be used.

When the passivation layer 70 comprises an organic material, the passivation layer 70 may include an insulating layer (not shown) comprising, for example, low-temperature amorphous silicon or amorphous silicon oxide under the passivation layer 70 to prevent an organic material of the passivation layer 70 from contacting an exposed portion of the semiconductor layer 40 between the source electrode 65 and the drain electrode 66.

Contact holes 77 and 78 that expose the drain electrode extension portion 67 and the data pad 68 are formed in the passivation layer 70. A contact hole 74 that exposes the gate pad 24 is formed in the passivation layer 70 and the gate insulating layer 30. The lateral profiles of the contact holes 74, 77, and 78 can be a substantially right angle.

A pixel electrode 82 that is electrically connected to the drain electrode 66 through the contact hole 77 and is located in a pixel is formed on the passivation layer 70. The pixel electrode 82 to which a data voltage is applied determines the arrangement of LC molecules of a liquid crystal layer between the pixel electrode 82 and a common electrode of an upper display panel by generating an electric field with the common electrode.

An auxiliary gate pad 84 connected to the gate pad 24 through the contact hole 74 and an auxiliary data pad 88 connected to the data pad 68 through the contact hole 78 are formed on the passivation layer 70. The pixel electrode 82 and the auxiliary gate and data pads 86 and 88 can comprise a transparent conductive oxide such as, for example, ITO or IZO.

Next, the method for fabricating a TFT plate according to an embodiment of the present invention is described with reference to FIGS. 7A and 7B and FIGS. 8A through 11B.

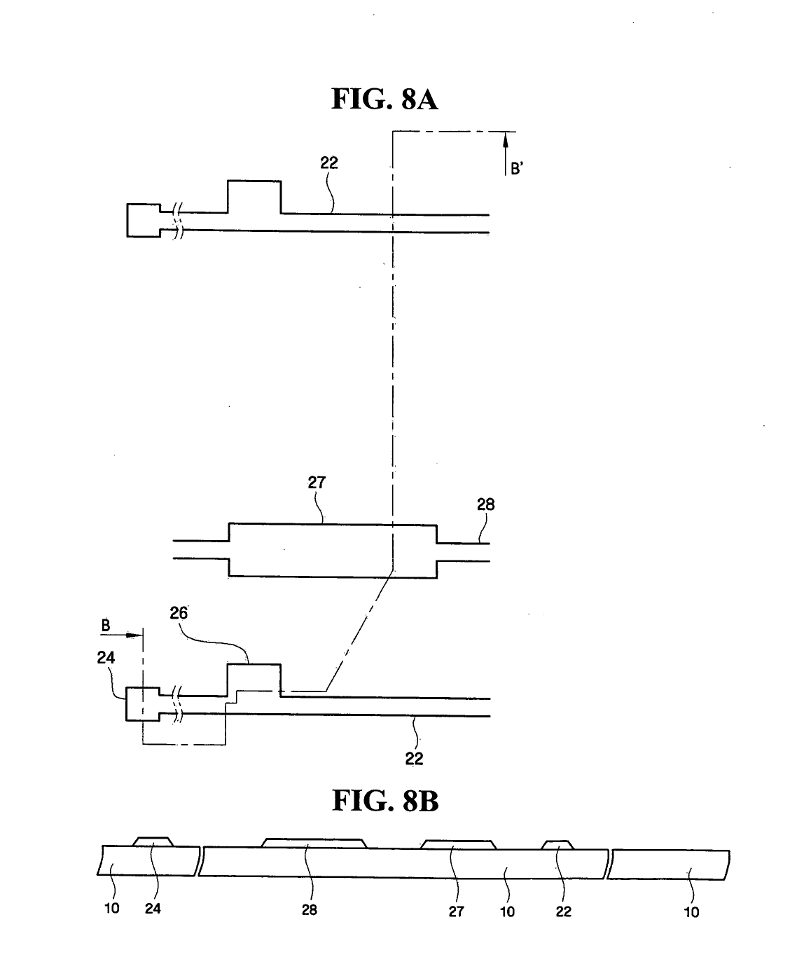

As shown in FIGS. 8A and 8B, the Ag conductive layer is formed with a thickness of about 1000 Å to about 3000 Å on the insulating substrate 10 using, for example, sputtering. Then, the gate wirings including the gate line 22 that extends horizontally, the gate pad 24 connected to the end of the gate line 22, the protruding gate electrode 26 connected to the gate line 22, and the storage electrode 27 and the storage electrode line 28 formed parallel with the gate line 22 are formed by patterning the Ag conductive layer. Before forming the Ag conductive layer, a transparent conductive oxide layer (not shown) comprising, for example, indium oxide such as ITO or IZO may be formed to improve the adhesion between the gate wirings 22, 24, 26, 27, and 28 and the substrate 10 and may be patterned along with the Ag conductive layer. After forming the Ag conductive layer, the transparent conductive oxide layer (not shown) may also be formed to improve the adhesion with an upper layer, for example, the gate insulating layer 30, and to prevent Ag from diffusing into the upper layer. The transparent conductive oxide layer may be patterned along with the Ag conductive layer. In an embodiment of the present invention, the patterning of the Ag conductive layer and the transparent conductive oxide layer can be performed by, for example, wet etching.

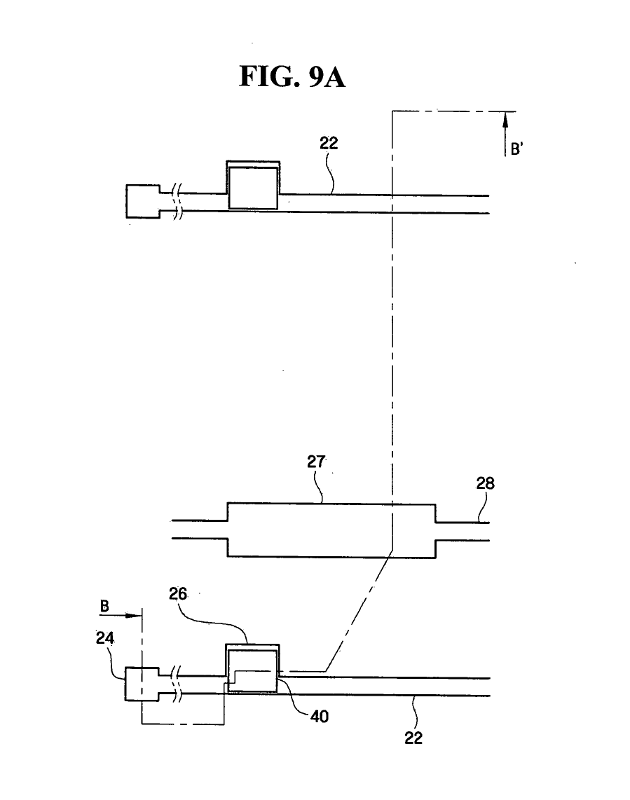

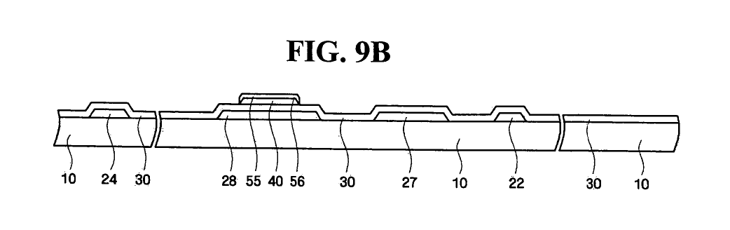

Referring to FIGS. 9A and 9B, the gate insulating layer 30 is deposited on the entire surface of the substrate 10 on which the gate wirings 22, 24, 26, 27, and 28 are formed. In an embodiment of the present invention, to prevent agglomeration of the gate wirings 22, 24, 26, 27, and 28 formed of an Ag conductive layer, the gate insulating layer 30 may be formed at a temperature of about 280° C. or lower. The gate insulating layer 30 may be, for example, a low-temperature amorphous silicon oxide layer or a low-temperature amorphous silicon nitride layer. In an embodiment of the present invention, the gate insulating layer 30 may be formed with a thickness of about 1500 Å to about 5000 Å.

Next, an intrinsic amorphous silicon layer and a doped amorphous silicon layer are continuously deposited on the gate insulating layer 30 with a thickness of about 500 Å to about 2000 Å and a thickness of about 300 Å to about 600 Å, respectively, using, for example, plasma chemical vapor deposition. Photolithography is performed on the intrinsic amorphous silicon layer and the doped amorphous silicon layer to form the semiconductor layer 40 in an island shape and the ohmic contact layers 55 and 56 on the gate insulating layer 30.

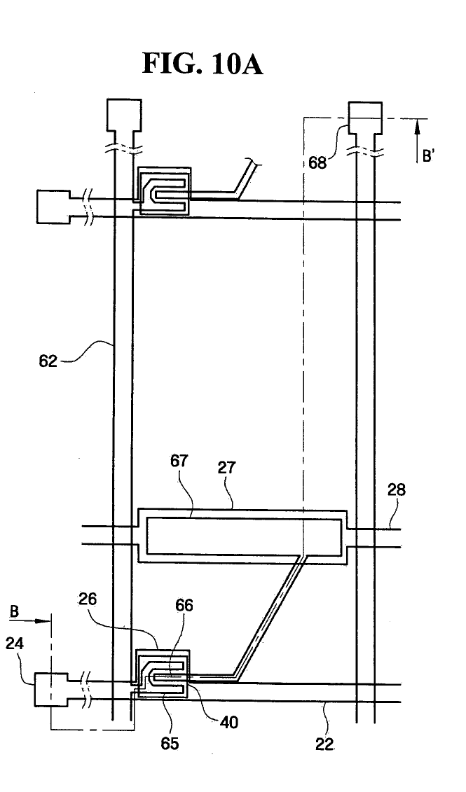

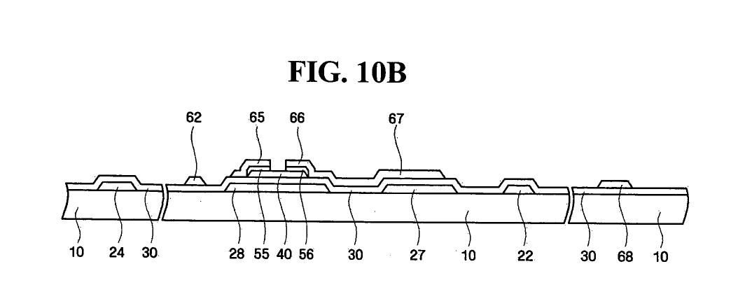

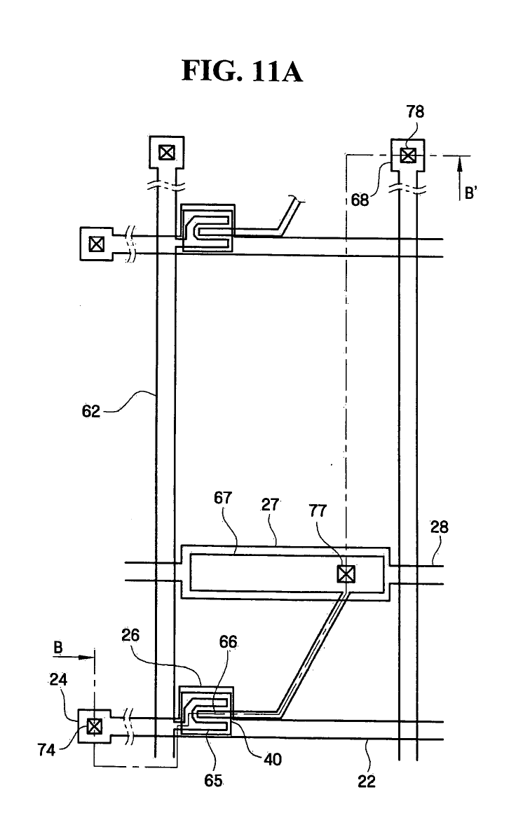

Referring to FIGS. 10A and 10B, the Ag conductive layer is formed on the gate insulating layer 30, an exposed portion of the semiconductor layer 40, and the ohmic contact layers 55 and 56. Photolithography is performed to form the data wirings including the data line 62 that intersects the gate line 22, the source electrode 65 that is connected to the data line 62 and extends onto the ohmic contact layer 55, the data pad 68 that is connected to an end of the data line 62, the drain electrode 66 that is separated from the source electrode 65 and is formed on the ohmic contact layer 56 opposite to the source electrode 65 on the gate electrode 26 or a channel portion of a TFT, and the drain electrode extension portion 67 with a large enough area that extends from the drain electrode 66 and overlaps the storage electrode 27. Before forming the Ag conductive layer, a transparent conductive oxide layer (not shown) comprising, for example, indium oxide such as ITO or IZO may be provided to improve the adhesion between each of the gate wirings 22, 24, 26, 27, and 28 and the substrate 10. The transparent conductive oxide layer may be patterned along with the Ag conductive layer. After forming the Ag conductive layer, the transparent conductive oxide layer (not shown) may also be formed to improve the adhesion with an upper layer, for example, the gate insulating layer 30, and to prevent Ag from diffusing into the upper layer. The transparent conductive oxide layer may be patterned along with the Ag conductive layer. In an embodiment of the present invention, the patterning of the Ag conductive layer and the transparent conductive oxide layer can be performed by, for example, wet etching.

Next, the data wirings 62, 65, 66, 67, and 68 are formed separated on both sides of the gate electrode 26 by etching portions of the doped amorphous silicon layer that are not covered by the data wirings 62, 65, 66, 67, and 68. A portion of the semiconductor layer 40 between the ohmic contact layers 55 and 56 is exposed. In an embodiment of the present invention, an oxygen plasma processing to stabilize the surface of the exposed portion of the semiconductor layer 40 can be performed.

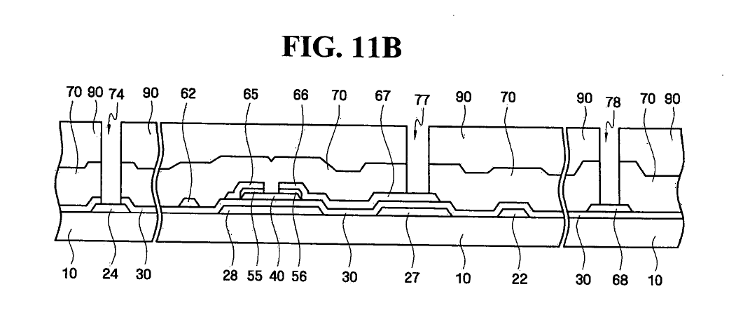

Referring to FIGS. 11A and 11B, the passivation layer 70 can be formed of a single layer or multiple layers including, for example, an organic material such as PFCB, BCB, or an inorganic material such as acryl, silicon nitride, or silicon oxide. The silicon nitride can be, for example, low temperature amorphous silicon nitride, and the silicon oxide can be, for example, low temperature amorphous silicon oxide. In an embodiment of the present invention, when the passivation layer 70 is formed using low-temperature amorphous silicon oxide or low-temperature amorphous silicon nitride, plasma chemical vapor deposition can be used.

The passivation layer 70 may be formed by, for example, spin coating or spinless coating using an organic material.

Next, the photosensitive layer is formed on the passivation layer 70 and is exposed and developed, thereby forming a photosensitive layer pattern 90. The gate insulating layer 30 and the passivation layer 70 are patterned using the photosensitive layer pattern 90 as an etching mask, thereby forming the contact hole 74 to expose the gate pad 24. Then, the passivation layer 70 is patterned, thereby forming the contact holes 77 and 78 that expose the drain electrode extension portion 67 and the data pad 68. Patterning of the gate insulating layer 30 and the passivation layer 70 is performed by, for example, dry etching including plasma etching.

Plasma etching may be performed by a plasma etch (PE) mode device using, for example, an anoxic gas including a fluorine based gas and a nitrogen gas. In an embodiment of the present invention, pressure may be in a range of about 200 mT to about 500 mT. The fluorine based gas may be at least one selected from the group consisting of SF₆, CF₄, CHF₃, or C₂F₆, and the mixing ratio of the fluorine based gas to the nitrogen (N2) gas may be, for example, in a range of about 2:1 to about 4:1 and may vary with the hardness or thickness of the insulating layer. In an embodiment of the present invention, an etch rate may be about 10000 Å/min.

Since the contact hole in an embodiment of the present invention can be formed by patterning a gate insulating layer and a passivation layer through plasma etching using a nitrogen gas having higher reactivity than an oxygen gas, the gate insulating layer and the passivation layer can be deposited at a low temperature. Thus an etch rate can be controlled even when the insulating layer is not solid enough. In addition, the lateral profile of the contact hole can be prevented from being inversely tapered and the lateral profile of the contact hole can be a substantially right angle. Moreover, since metal wirings exposed by the contact hole, for example, the gate pad, the data pad, and the drain electrode extension portion are not affected by an etching gas, the gate pad, the data pad, and the drain electrode extension portion can be prevented from being oxidized and discolored.

Next, a transparent conductive oxide layer is formed of, for example, ITO or IZO on the passivation layer 70 and then photolithography is performed to form the pixel electrode 82 connected to the drain electrode 66 through the contact hole 77 and the auxiliary gate and data pads 84 and 88 connected to the gate and data pads 24 and 68 through the contact holes 74, and 78, respectively.

The contact hole forming method according to an embodiment of the present invention may be applied to a TFT plate having a bottom gate type TFT in which a gate electrode is formed under a semiconductor layer and a TFT plate having a top gate type TFT in which a gate electrode is formed on a semiconductor layer. Although a semiconductor layer and data wirings are formed through photolithography using different masks in the method for fabricating a TFT plate, the method for forming a contact hole according to an embodiment of the present invention can also be applied to a method for fabricating a TFT plate in which a semiconductor layer and data wirings are formed by photolithography using one photosensitive layer pattern.

According to embodiments of the present invention, an improved lateral profile of a contact hole can be provided by controlling the etch rate of a low-temperature deposition insulating layer. In addition, corrosion of a metal wiring under the insulating layer can be prevented.

Although exemplary embodiments of the present invention have been described with reference to the accompanying drawings, it is to be understood that the present invention should not be limited to these precise embodiments but various changes and modifications can be made by one skilled in the art without departing from the spirit and scope of the present invention as hereinafter claimed.

What is claimed is:

1. A method for forming a contact hole, comprising:
forming a conductive layer on a substrate;
patterning the conductive layer to form a wiring;
forming an insulating layer on the wiring and the substrate through a low temperature deposition process; and
dry etching the insulating layer using an anoxic gas to expose the wiring.

2. The method of claim 1, wherein the wiring comprises silver (Ag).

3. The method of claim 1, wherein the anoxic gas includes a fluorine based gas and a nitrogen gas.

4. The method of claim 3, wherein the fluorine based gas includes at least one of SF₆, CF₄, CHF₃, or C₂F₆.

5. The method of claim 3, wherein the mixing ratio of the fluorine based gas to the nitrogen gas is in a range of about 2:1 to about 4:1.

6. The method of claim 1, wherein the dry etching includes plasma etching.

7. The method of claim 1, wherein the lateral profile of the contact hole is substantially a right angle.

8. The method of claim 1, wherein the low temperature deposition process is performed at a temperature of about 280° C. or lower.

9. The method of claim 1, wherein the low temperature deposition process includes plasma chemical vapor deposition.

10. The method of claim 1, wherein the insulating layer includes an organic layer, a low temperature amorphous silicon oxide layer, or a low temperature amorphous silicon nitride layer.

11. A method for fabricating a thin film transistor (TFT) plate, the method comprising:
forming a gate wiring including a gate line that extends in a first direction on a substrate;
forming a first insulating layer covering the gate wiring using a first low temperature deposition process;
forming a data wiring including the data line that extends in a second direction to intersect the gate line on the first insulating layer;
forming a second insulating layer covering the data wiring using a second low temperature deposition process; and
forming a contact hole that exposes the gate wiring or the data wiring by dry etching the first insulating layer and the second insulating layer or by dry etching the second insulating layer using an anoxic gas.

12. The method of claim 11, wherein the anoxic gas includes a fluorine based gas and a nitrogen gas.

13. The method of claim 12, wherein the fluorine based gas includes at least one of SF₆, CF₄, CHF₃, or C₂F₆.

14. The method of claim 12, wherein the mixing ratio of the fluorine based gas to the nitrogen gas is in a range of about 2:1 to about 4:1.

15. The method of claim 11, wherein the dry etching including plasma etching.

16. The method of claim 11, wherein the lateral profile of the contact hole is substantially a right angle.

17. The method of claim 11, wherein the first and second low temperature deposition processes are performed at a temperature of about 280° C. or lower.

18. The method of claim 11, wherein the first and second low temperature deposition processes include plasma chemical vapor deposition.

19. The method of claim 11, wherein at least one of the gate wiring or the data wiring includes silver (Ag).

20. The method of claim 11, wherein the first and second insulating layers include an organic layer, a low temperature amorphous silicon oxide layer, or a low temperature amorphous silicon nitride layer.

21. The method of claim 11, wherein the first insulating layer is a gate insulating layer and the second insulating layer is a passivation layer.

22. The method of claim 11, wherein the first direction is substantially orthogonal to the second direction.
